(19) United States
(12) Patent Application Publication
(10) Pub. No.: US 2024/0198366 A1
(43) Pub. Date: Jun. 20, 2024

(54) APPARATUS AND METHOD FOR MEASURING FLOW CONDUCTANCE OF SHOWERHEAD ASSEMBLY

(71) Applicant: ASM IP Holding B.V., Almere (NL)

(72) Inventors: Dinkar Nandwana, Chandler, AZ (US); Allen D'Ambra, Phoenix, AZ (US); Dinh Tran, Tempe, AZ (US); Chen Ni, Phoenix, AZ (US); Gary Paulsen, Phoenix, AZ (US); Michael Samy Boulos Hanna Elkomos, Chandler, AZ (US)

(21) Appl. No.: 18/540,419

(22) Filed: Dec. 14, 2023

Related U.S. Application Data
(60) Provisional application No. 63/387,844, filed on Dec. 16, 2022.

(51) Int. Cl. B05B 1/30; B05B 1/00; B05B 1/18

(52) U.S. Cl. CPC B05B 1/3006; B05B 1/005; B05B 1/185

(57) ABSTRACT

Methods and apparatuses for measuring a flow conductance of a showerhead assembly are described. For example, a showerhead assembly may be seated in a housing. A gas source may be coupled to an intake port of the showerhead assembly and supply gas to the showerhead assembly via the intake port. A pressure controller may be coupled between the gas source and the showerhead assembly. The pressure controller may measure a flow throughput of the gas that passes through the pressure controller. The pressure controller may maintain the gas being supplied to the showerhead assembly at a first pressure value. A pressure transducer coupled to an exhaust port of the showerhead assembly may measure a second pressure value. A controller may determine a flow conductance of the showerhead assembly based on the flow throughput and the first and second pressure values.

### CROSS-REFERENCE TO RELATED APPLICATION(S)

This Application claims the benefit of U.S. Provisional Application 63/387,844 filed on Dec. 16, 2022, the entire contents of which are incorporated herein by reference.

### TECHNICAL FIELD

The present disclosure generally relates to an apparatus and a method for measuring flow conductance of a showerhead assembly.

### BACKGROUND

Semiconductor devices are manufactured in process chambers. A process chamber may include a showerhead assembly through which precursor reactants may be sprayed and deposited onto a substrate, such as a silicon wafer. However, the performance, for example a flow conductance, of the showerhead assembly may degrade over time due to the gradual accretion of residual reactants on the surfaces of the showerhead, including its many apertures. Removing and replacing a used showerhead assembly for a new may be costly because of the cost of the new showerhead assembly, and because of the unavoidable downtime of the process chamber. In order to minimize such costs, a used showerhead may be refurbished to prolong its lifespan, and an assurance that the replaced refurbished showerhead would perform up to the expected standard would be valuable in reducing the downtime of the process chamber during the replacement process.

### SUMMARY

The following presents a simplified summary of various aspects described herein. This summary is not an extensive overview, and is not intended to identify key or critical elements or to delineate the scope of the claims. The following summary merely presents some concepts in a simplified form as an introductory prelude to the more detailed description provided below.

One or more aspects are described for measuring a flow conductance of a showerhead assembly. In one aspect, a system may include one or more of the following: a housing, a showerhead assembly seated in the housing, a gas source coupled to an intake port of the showerhead assembly and configured to supply gas to the showerhead assembly via the intake port, a pressure controller coupled between the gas source and the showerhead assembly and configured to measure a flow throughput of the gas that passes through the pressure controller, a pressure transducer coupled to the exhaust port of the showerhead assembly, and a controller. The controller may be configured to cause the pressure controller to maintain the gas being supplied from the gas source to the showerhead assembly at a first pressure value, receive, from the pressure transducer, a second pressure value, and determine a flow conductance of the showerhead assembly based on the flow throughput, the first pressure value, and the second pressure value.

In another aspect, a flow conductance measuring device may include a pressure controller configured to supply intake gas to a showerhead assembly at a first pressure value and measure a flow throughput of the supplied intake gas, a pressure transducer configured to measure a second pressure value of an exhaust gas, and a controller configured to determine a flow conductance of the showerhead assembly based on the flow throughput, the first pressure value, and the second pressure value.

In a further aspect, a method may include causing, by a controller, an intake gas to be supplied to a showerhead assembly via an intake conduit at a first pressure value, receiving an indication of a flow throughput of the intake gas, receiving an indication of a second pressure value of an exhaust gas being expelled from the showerhead assembly that is measured at an exhaust conduit coupled to the showerhead assembly, and determining, based on the flow throughput, the first pressure value, and the second pressure value, a flow conductance of the showerhead assembly.

Additional aspects, configurations, embodiments, and examples are described in more detail below.

### BRIEF DESCRIPTION OF DRAWINGS

Some features are shown by way of example, and not by limitation, in the accompanying drawings. In the drawings, like numerals reference similar elements.

FIG. 1 shows a cross-sectional view of an example reactor.

FIG. 2 shows a cross-sectional view of an example shower head assembly coupled to a blank-off plate.

FIG. 3 shows a view of an example orifice flow system.

FIG. 4A shows a block diagram of an example device for measuring a flow conductance of a showerhead assembly.

FIG. 4B shows a detailed view of an example device for measuring a flow conductance of a showerhead assembly.

FIG. 5 shows an example flow profile of a showerhead assembly.

FIG. 6 shows an example flowchart describing a process for measuring a flow conductance of a showerhead assembly.

FIG. 7 shows an example system architecture of a device.

It will be recognized by the skilled person in the art, given the benefit of this disclosure, that the exact arrangement, sizes and positioning of the components in the figures is not necessarily to scale or required.

### DETAILED DESCRIPTION

One or more aspects of the disclosure relate to measuring a flow conductance of a showerhead assembly that may be used to process semiconductor wafers and/or other substrates. As used herein, the term substrate may refer to any underlying material or materials upon which a layer may be deposited. A substrate may include a bulk material, such as silicon (e.g., single-crystal silicon) or other semiconductor material, and may include one or more layers, such as native oxides or other layers, overlying or underlying the bulk material. Further, the substrate may include various topologies, such as recesses, lines, and the like formed within or on at least a portion of a layer and/or bulk material of the substrate. By way of particular examples, a substrate may comprise one or more materials including, but not limited to, silicon (Si), germanium (Ge), germanium tin (GeSn), silicon germanium (SiGe), silicon germanium tin (SiGeSn), silicon carbide (SiC), or a group III-V semiconductor material, such as, for example, gallium arsenide (GaAs), gallium phosphide (GaP), or gallium nitride (GaN). In some embodiments, the substrate may comprise one or more dielectric materials including, but not limited to, oxides, nitrides, or oxynitrides. For example, the substrate may comprise a silicon oxide (e.g., SiO₂), a metal oxide (e.g., Al₂O₃), a silicon nitride (e.g., Si₃N₄), or a silicon oxynitride. In some embodiments of the disclosure, the substrate may comprise an engineered substrate wherein a surface semiconductor layer is disposed over a bulk support with an intervening buried oxide (BOX) disposed therebetween. The substrate may contain one or more monocrystalline surfaces and/or one or more other surfaces that may comprise a non-monocrystalline surface, such as a polycrystalline surface and/or an amorphous surface. The substrate may include a layer comprising a metal, such as copper, cobalt, and the like.

The terms precursor gas and/or precursor gasses may refer to a gas or combination of gasses that participate in a chemical reaction that produces another compound. For example, precursor gasses may be used to grow an epitaxial layer comprising silicon carbide. Precursor gasses may include a deposition gas or gasses, a dopant gas or gasses, or a combination of a deposition gas or gasses and a dopant gas or gasses.

In the following description of the various embodiments, reference is made to the accompanying drawings, which form a part hereof, and in which is shown by way of illustration various embodiments in which aspects of the disclosure may be practiced. It is to be understood that other embodiments may be utilized and structural and functional modifications may be made without departing from the scope of the present disclosure. Aspects of the disclosure are capable of other embodiments and of being practiced or being carried out in various ways. Also, it is to be understood that the phraseology and terminology used herein are for the purpose of description and should not be regarded as limiting. Rather, the phrases and terms used herein are to be given their broadest interpretation and meaning. The use of “including” and “comprising” and variations thereof is meant to encompass the items listed thereafter and equivalents thereof as well as additional items and equivalents thereof. While various directional arrows are shown in the figures of this disclosure, the directional arrows are not intended to be limiting to the extent that bi-directional communications are excluded. Rather, the directional arrows are to show a general flow of steps and not the unidirectional movement of information. In the entire specification, when an element is referred to as “comprising” or “including” another element, the element should not be understood as excluding other elements so long as there is no special conflicting description, and the element may include at least one other element. Throughout the specification, expressions such as “at least one of a, b, and c” may include “a only,” “b only,” “c only,” “a and b,” “a and c,” “b and c,” and/or “all of a, b, and c.”

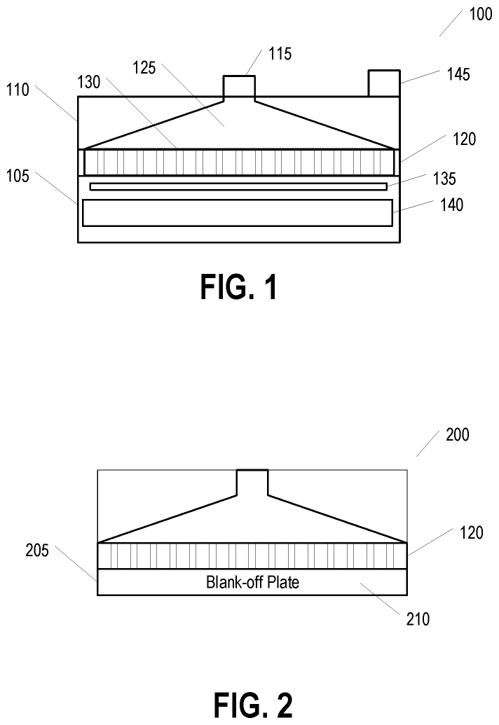

FIG. 1 shows a cross-sectional view of an example reactor. A reactor 100 (also referred to as a process chamber) may be a deposition reactor such as an atomic layer deposition (ALD) reactor. The reactor 100 may have a bottom chamber 105 (e.g., a reaction space) and a showerhead assembly 110. The showerhead assembly 110 may further include a transfer tube 115 and a showerhead 120. A gas (e.g., a precursor gas, a reactant, etc.) may be introduced via the transfer tube 115 into a top cavity 125 of the showerhead assembly 110. The showerhead 120 may be circular in shape but it may have other shapes. The showerhead 120 may have a plurality of apertures 130. Each of the plurality of apertures 130 may be a through hole that allows the gas to travel from the top cavity 125 to the bottom chamber 105 and be evenly distributed on the surface of a substrate 135. Each of the plurality of apertures 130 may be of various shapes and sizes. For example, each of the plurality of apertures 130 may be a round tube of about 0.8-1.2 mm (e.g., 1 mm) in diameter and 15-25 mm in length.

The gas that is emitted to the bottom chamber 105 via the plurality of apertures 130 may be deposited as a thin film on the substrate 135. The film may have a thickness at an atomic level. Any residual gas (e.g., precursor) that is not deposited on the substrate 135 may be expelled out of the bottom chamber 105 via an exhaust port (not shown). In some variations, the showerhead 120 may include an exhaust port 145. For example, the showerhead 120 may be a dual plenum system with a first (e.g., inner) plenum for gas to enter and a second (e.g., outer) plenum for gas to exhaust (e.g., via the exhaust port 145).

The substrate 135 may be, for example, a 300 mm diameter silicon wafer to be deposited with a material layer on it. The substrate 135 may be placed on a substrate support 140, which may be a heater (e.g., resistive heater, ceramic heater) having a heating element embedded in it to keep the substrate 135 (e.g., a semiconductor wafer) at a specified temperature. The substrate support 140 may be raised or lowered using one or more lift pins (not shown). The substrate 135 may be slid in and out of the bottom chamber 105 while the substrate support 140 is in its lowered position. The substrate support 140 may be used for supporting or heating the substrate 135 during deposition of material layers onto the substrate 135, such as deposition of molybdenum-containing material layers onto the substrate. The substrate support 140 may resistively heat the substrate 135 to a desired deposition temperature, for example, between about 200 degrees Celsius and 400 degrees Celsius. The substrate support 140 may be formed from a metallic material, such as Hastelloy®, which exhibits a corrosion resistance. The substrate support 140 may alternatively be formed from aluminum nitride, stainless steel, and/or aluminum.

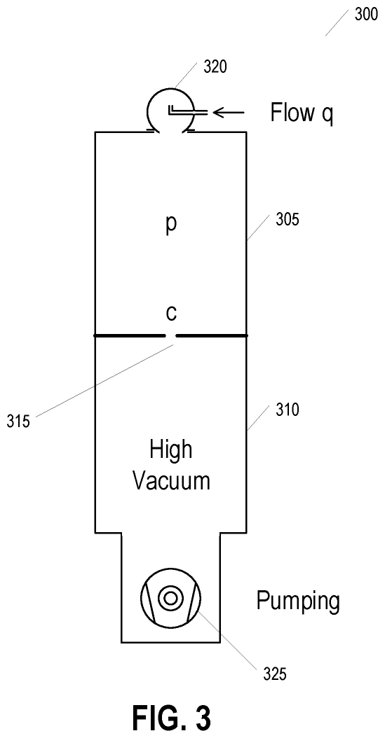

Over time (e.g., after a few cycles of deposition operations), the plurality of apertures 130 may collect residual reactants accreted on the inner surfaces of the plurality of apertures 130. These accreted reactants may partially or entirely block the flow of gas passing through the plurality of apertures 130, and thus reduce the effective flow area of the plurality of apertures 130. As a result, a flow conductance of the showerhead assembly 110 may degrade over time and/or after multiple uses. A flow conductance (e.g., a vacuum conductance) of a reaction chamber is a key indicator that quantifies the total flow through the reaction chamber for a given pressure drop. A more detailed description of the flow conductance will be provided with reference to FIG. 2. After repeated deposition operations, the flow conductance of the reactor 100 may decrease and the uniformity of thickness of the film deposited on the substrate 135 may also decrease. Variation may be introduced to the thickness of the film depending on the location on the substrate 135 due to the uneven flows of gas being emitted from the plurality of apertures 130 having varying degrees of occlusion. Thus, the showerhead assembly 110 may require regular cleaning operations to remove residual reactants on its surfaces and restore its flow conductance to its original, or near-original state, or to within a predetermined level or levels.

For example, an operator may remove a used showerhead assembly and replace it with a spare (e.g., new or refurbished) showerhead assembly, and then ship the used showerhead assembly to a facility, such as an authorized cleaning house, to have the showerhead assembly serviced (e.g., cleaned, refurbished, etc.). The cleaning operation may involve exposing the inner and/or outer surfaces of the showerhead assembly 110 (e.g., the transfer tube 115, the showerhead 120, the top cavity 125, the plurality of apertures 130, etc.) to a chemistry, which is formulated to remove residual accreted precursor reactants. After the showerhead assembly has been cleaned in this way, the restored showerhead assembly may be returned to an operator to be installed in a reactor again. However, how well the cleaning operation was conducted may not be evident until the showerhead assembly is placed back in the reactor 100 and a cycle of deposition operation is performed. If the flow characteristic of the showerhead assembly 110 does not meet the required specification, the showerhead assembly 110 may need to be taken off and serviced again, which further lengthens the down time of the reactor 100. Thus, it may be beneficial to have a way to measure the flow conductance of the showerhead assembly 110 offline (e.g., outside of the reactor 100 environment).

FIG. 2 shows a cross-sectional view of an example shower head assembly coupled to a blank-off plate. A showerhead assembly 200 may be removed from the reactor 100 environment and a blank-off plate may be coupled to the showerhead 120. The blank-off plate 205 may form a seal around the showerhead 120 and create a bottom cavity 210. The bottom cavity 210 may be connected to an exhaust port (not shown), through which an exhaust gas may be expelled. The blank-off plate 205 may be removable and coupled to the showerhead 120 to test the flow conductance of the showerhead assembly 200.

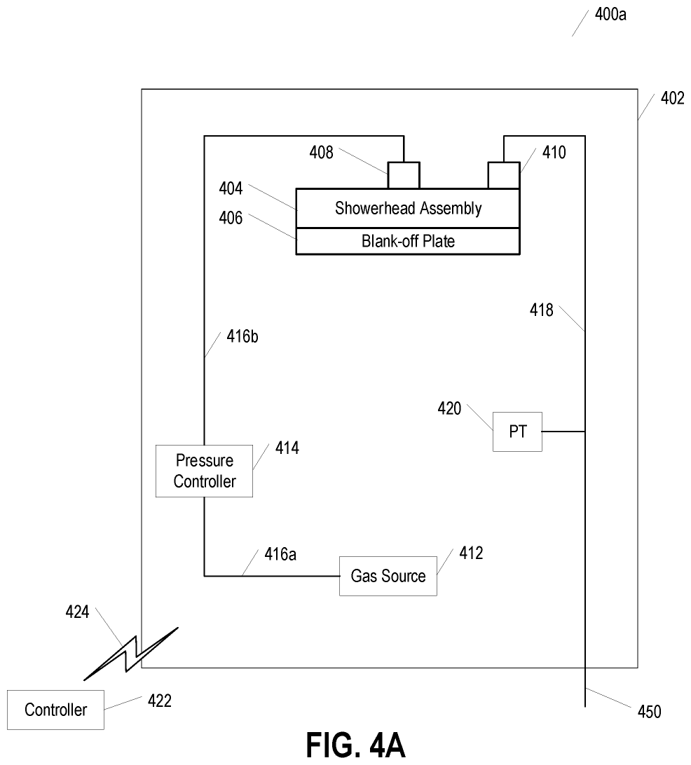

FIG. 3 shows a view of an example orifice flow system 300. The orifice flow system 300 may demonstrate the relationship between a chamber pressure, a flow throughput, and a flow conductance. The orifice flow system 300 may consist of a first chamber 305 and a second chamber 310 that are separated from each other by a divider with a small orifice 315. A gas flow may be introduced at an intake port 320 at one end of the first chamber 305 and be pumped out from an end of the second chamber 310 via a pump 325 (e.g., vacuum pump). The pumping operation may create a high vacuum environment in the second chamber 310. When the flow of gas being introduced to the intake port 320 is q, the pressure p inside the first chamber 305 may be expressed with the formula, p≈ q/C, where C is the flow conductance of the orifice flow system 300.

Flow conductance may also be expressed in the following formula, Q=(P₁−P₂)·C, where Q is the total throughput, P₁ and P₂ are upstream and downstream pressures (e.g., at 320 and 325), and C is the flow conductance. The pressures P₁ and P₂ may be measured in units such as Torr. The flow throughput (Q) (also referred to as a “flow,” a “throughput,” or a “flow pressure throughput”) may be measured as a mass throughput but alternatively measured as a pressure throughput having units of pressure times volume per second, such as standard liter per minute (slm). The conductance (C) may have units of volume per time, such as (slm/Torr), and may have the same units as the pumping speed of a vacuum pump.

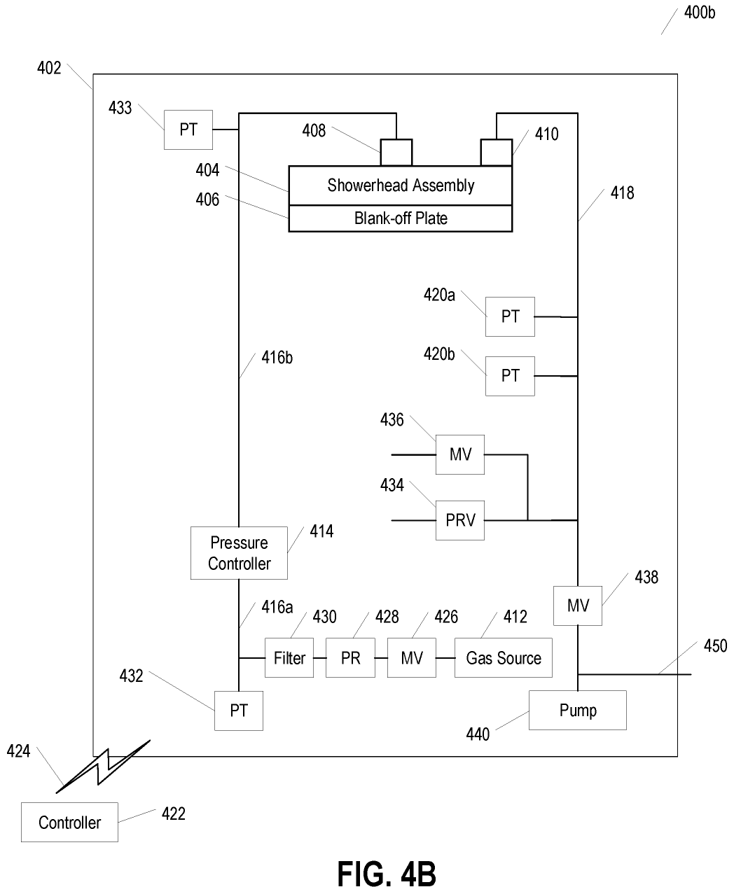

FIG. 4A shows a block diagram of an example device for measuring a flow conductance of a showerhead assembly (e.g., the showerhead assembly 120, the showerhead assembly 404, etc.). A conductance test fixture 400a may have a housing 402, in which a showerhead assembly 404 is seated. The showerhead assembly 404 may include a blank-off plate 406 that creates a testing environment by making a seal around the showerhead assembly 404. The blank-off plate 406 may mimic the vacuum environment in which the showerhead assembly 404 may be used in a reactor. The showerhead assembly 404 may also include an intake port 408 and an exhaust port 410. The showerhead assembly 404 may have a dual plenum system. Intake gas may enter the showerhead assembly 404 (e.g., an inner plenum of the showerhead assembly 404) via the intake port 408, pass through the apertures in the showerhead, enter the blank-off plate 406 (e.g., connected to an outer plenum of the showerhead assembly 404), and leave the showerhead assembly 404 via the exhaust port 410 as exhaust gas.

The intake gas may originate from a gas source 412. The gas source 412 may be located inside the housing 402 (e.g., as illustrated), or it may be located outside the housing 402. The gas may be an inert gas. For example, the gas may be nitrogen (N₂), ammonia (NH₃), silane (SiH₄), hydrogen (H₂), argon (Ar), krypton (Kr), etc. The gas source 412 may be coupled to a pressure controller 414 via a conduit 416a. The conduit 416a and other conduits as described herein may be a flexible hose.

The pressure controller 414 (also referred to as a pressure flow controller) may be coupled to conduits 416a and 416b (collectively, 416) and regulate the pressure of the gas that is permitted to pass through the conduit 416. In lieu of or in combination with the pressure controller 414, a mass flow controller (MFC) may be used to keep the flow of the gas while varying the pressure. The pressure controller 414 may be a mass flow controller. For example, the pressure controller 414 may regulate the gas being provided by the gas source 412 to the intake port 408 of the showerhead assembly 404 while maintaining the pressure of the gas at a specified pressure value and measuring the flow throughput of the gas in the conduit 416b.

The exhaust port 410 of the showerhead assembly 404 may be coupled to a conduit 418. Any exhaust gas being expelled through the exhaust 410 may be routed through the conduit 418. A pressure transducer 420 may be coupled to the conduit 418 to measure the pressure of the exhaust gas passing through the conduit 418. The pressure transducer 420 may be, for example, a pressure sensor. The exhaust gas would eventually exit the conduit 418 at an end 450.

A controller 422 may be located inside the housing 402 or located outside the housing 402 (e.g., as illustrated). The controller 422 may communicate with one or more components (e.g., the gas source 412, the pressure controller 414, the showerhead assembly 404, the pressure transducer 420, etc.) of the conductance test fixture 400a via wired or wireless communication 424. The controller 422 may include, for example, a processor (e.g., a central processing unit), memory (e.g., random access memory (RAM), read-only memory (ROM), etc.), storage (e.g., a hard disk drive, a magnetic disc, a solid-state drive (SSD), etc.), a communication interface (e.g., Ethernet, Wi-Fi, Bluetooth, near-field communication (NFC), etc.), an input device (e.g., a keyboard, a mouse, a touchscreen, a microphone, etc.), an output device (e.g., a display, a printer, a speaker, etc.), etc. For example, the controller 422 may be a personal computer (PC), a laptop computer, a tablet computer, a mobile device, a smartphone, a wearable device, etc. The communication 424 may be wired communication, such as Ethernet, Universal Serial Bus (USB), serial port communication, parallel port communication, etc. The communication 424 may be wireless communication, such as Wi-Fi, Wi-Fi Direct, Bluetooth, NFC, infrared communication, etc. The communication 424 may include a combination of both wired and wireless communication.

The controller 422 may control one or more components of the conductance test fixture 400a and/or exchange data with one or more components of the conductance test fixture 400a. For example, the controller 422 may send a command to the pressure controller 414 to maintain the pressure at a specified pressure value. The controller 422 may receive, from the pressure controller 414, an indication of the current pressure value at the conduit 416b and/or an indication of a flow throughput of the conduit 416b. The controller 422 may receive, from the pressure transducer 420, an indication of the current pressure value at the conduit 418. The controller 422 may send a command to the gas source 412 to start or stop the flow of the gas.

Based on the data that the controller 422 receives from other component(s) of the conductance test fixture 400a, the controller 422 may determine the flow conductance of the showerhead assembly 404. For example, the pressure controller 422 may control the pressure controller 414 to maintain a fixed pressure P₁ at the intake conduit 416b, and receive a pressure value P₂ from the pressure transducer 420. The controller 422 may receive, from the pressure controller 414, an indication of a flow throughput Q. Using the delta pressure (P₁−P₂) and the flow Q, the flow conductance of the showerhead assembly 404 may be measured as Q/(P₁−P₂). The controller 422 may vary the pressure P₁ at the intake conduit 416b and measure flow conductance values at different pressure values. Based on these multiple flow conductance values, the controller 422 may generate overall flow characteristics of the showerhead assembly 404. The flow characteristics of the showerhead assembly 404 may also be referred to as a flow profile or a flow fingerprint of the showerhead assembly 404. The controller 422 may output the flow characteristics of the showerhead assembly 404 by displaying them on a screen, creating a computer-readable file, etc.

FIG. 4B shows a detailed view of an example device for measuring a flow conductance of a showerhead assembly. A conductance test fixture 400b may be similar to the conductance test fixture 400a in many respects. The conductance test fixture 400b may have a housing 402, in which a showerhead assembly 404 is seated. The showerhead assembly 404 may include a blank-off plate 406 that creates a testing environment by making a seal around the showerhead assembly 404. The blank-off plate 406 may mimic the vacuum environment in which the showerhead assembly 404 may be used in a reactor. The showerhead assembly 404 may also include an intake port 408 and an exhaust port 410. Intake gas may enter the showerhead assembly 404 via the intake port 408, pass through the apertures in the showerhead, enter the blank-off plate 406, and leave the showerhead assembly 404 via the exhaust 410 as exhaust gas. Optionally, the intake port 408 may include a pulse valve manifold (PVM) that allows mixing of multiple gasses. A pressure transducer 433 may be coupled to the intake conduit 416b to measure the pressure of the intake gas entering the showerhead assembly 404. The pressure transducer 433 may send one of more signals (e.g., measurements) to the controller 422.

The intake gas may originate from a gas source 412. The gas source 412 may be located inside the housing 402, or it may be located outside the housing 402. The gas may be an inert gas. For example, the gas may be nitrogen (N₂), ammonia (NH₃), silane (SiH₄), hydrogen (H₂), argon (Ar), krypton (Kr), etc. The gas source 412 may be coupled to a pressure controller 414 via a conduit 416a. The conduits 416a, 416b, 418 may be a flexible hose.

Between the gas source 412 and the pressure controller 414, other components such as a manual valve 426, a pressure regulator 428, a filter 430, and/or a pressure transducer 432 may be coupled to the intake conduit 416a. These components may be connected in serial in any order. For example, the manual valve 426 may be coupled to the conduit 416a upstream of the pressure regulator 428 or downstream of the pressure regulator 428, and so forth. The manual valve 426 may be a mechanical valve that a user can manipulate to partially or completely shut off the gas from the gas source 412 from entering the pressure controller 414 and the showerhead assembly 404. The pressure regulator 428 may regulate the pressure of the gas passing through the conduit 416a. For example, the gas source 412 may be designed to maintain its gas pressure at around 60-80 pounds per square gauge (PSIG). On the other hand, the pressure regulator 428 may lower the pressure to around 0-30 PSIG. The filter 430 may be placed on the intake conduit 416a to filter out any debris or impurities that may be contained in the gas. The pressure transducer 432 may be a pressure sensor that measures the pressure of the intake gas and sends the data to the controller 422 via wired or wireless communication 424.

The pressure controller 414 (also referred to as a pressure flow controller) may be coupled to the conduit 416 and regulate the pressure of the intake gas passing through the intake conduit 416. A mass flow controller, which can regulate the flow of the intake gas, may be used instead of or in combination with the pressure controller 414. The pressure controller 414 may be a mass flow controller. For example, the pressure controller 414 may regulate the gas being provided by the gas source 412 to the intake port 408 of the showerhead assembly 404 while maintaining the pressure of the gas at a specified pressure value and measuring the flow throughput of the gas.

The exhaust port 410 of the showerhead assembly 404 may be coupled to the exhaust conduit 418. Any exhaust gas being expelled through the exhaust 410 may be routed through the conduit 418. Pressure transducers 420a and 420b (collectively, pressure transducers 420) may be coupled to the conduit 418 to measure the pressure of the exhaust gas passing through the exhaust conduit 418. The pressure transducers 420 may be, for example, pressure sensors. The pressure transducer 420a and the pressure transducer 420b may each have a different range and/or resolution from each other. For example, the pressure transducer 420a may be capable of effectively measuring pressure values in the range of 0-10 Torr with the resolution of 0.1 Torr, while the pressure transducer 420b may be capable of effectively measuring pressure values in the range of 0-1000 Torr with the resolution of 10 Torr. The pressure transducers 420 may transmit their measurements to the controller 422 via the wired or wireless communication 424. The controller 422 may selectively use the measurement values that it received from the pressure transducers 420. For example, for greater accuracy, the controller 422 may use the value obtained from the pressure transducer 420a if the measured pressure value is in the 0-10 Torr range, and the controller 422 may use the value obtained from the pressure transducer 420b if the measured pressure value is in the 10-1000 Torr range.

A pressure relief valve 434 may be coupled to the exhaust conduit 418 as a failsafe measure. If the pressure in the exhaust conduit 418 reaches or exceeds a specified pressure, the pressure relief valve 434 may be automatically opened to relieve the pressure by allowing some of the exhaust gas to escape. A manual valve 436 may be coupled next to the pressure relief valve 434 to allow atmospheric gas to enter the exhaust conduit 418 to neutralize the pressure. Another manual valve 438 may be coupled to the exhaust conduit 418 to allow the user to manually obstruct the exhaust conduit 418.

A pump 440 (e.g., a dry pump) may be coupled to the exhaust conduit 418. The pump 440 may pump out the exhaust gas to create a low pressure or vacuum environment in the exhaust conduit 418. The exhaust gas would eventually exit the conduit 418 at an end 450.

The controller 422 may be located inside the housing 402 or located outside the housing 402. The controller 422 may communicate with one or more components (e.g., the gas source 412, the pressure controller 414, the showerhead assembly 404, the pressure transducer 420a, the pressure transducer 420b, the pressure regulator 428, the pressure transducer 432, the pressure transducer 433, the dry pump 440, etc.) of the conductance test fixture 400b via the wired or wireless communication 424. The controller 422 may include, for example, a processor (e.g., a CPU), memory (e.g., RAM, ROM, etc.), storage (e.g., a hard disk drive, a magnetic disc, an SSD, etc.), a communication interface (e.g., Ethernet, Wi-Fi, Bluetooth, NFC, etc.), an input device (e.g., a keyboard, a mouse, a touchscreen, a microphone, etc.), an output device (e.g., a display, a printer, a speaker, etc.), etc. For example, the controller 422 may be a PC, a laptop computer, a tablet computer, a mobile device, a smartphone, a wearable device, etc. The communication 424 may be wired communication, such as Ethernet, USB, serial port communication, parallel port communication, etc. The communication 424 may be wireless communication, such as Wi-Fi, Wi-Fi Direct, Bluetooth, NFC, infrared communication, etc. The communication 424 may include a combination of both wired and wireless communication.

The controller 422 may control one or more components of the conductance test fixture 400b and/or exchange data with one or more components of the conductance test fixture 400b. For example, the controller 422 may send a command to the pressure controller 414 to maintain the pressure at a specified pressure value or change the pressure to a specified pressure value. The controller 422 may receive, from the pressure controller 414, an indication of the current pressure value at the conduit 416b and/or an indication of a flow throughput of the conduit 416b. The controller 422 may receive, from the pressure transducers 422, one or more indications of the current pressure value at the conduit 418. The controller 422 may send a command to the gas source 412 to start or stop the flow of the gas. The controller 422 may send a command to the pressure regulator 428 to regulate the intake gas pressure within a specified range. The controller 422 may send a command to the dry pump 440 to set its pumping speed. The controller 422 may receive measurement values from other components (e.g., the pressure controller 414, the pressure transducers 422, etc.) either synchronously or asynchronously. For example, the controller 422 may send a request command to another component and receive a measurement value in response. Alternatively, the other component(s) may send measurement values to the controller 422 periodically (e.g., once every second) without receiving any requests.

Based on the data that the controller 422 receives from other component(s) of the conductance test fixture 400b, the controller 422 may determine the flow conductance of the showerhead assembly 404. For example, the pressure controller 422 may control the pressure controller 414 to maintain a fixed pressure P₁ at the intake conduit 416b, and receive a pressure value P₂ from the pressure transducers 420. The controller 422 may alternatively receive the intake pressure P₁ from the pressure transducer 433. The controller 422 may receive, from the pressure controller 414, an indication of a flow throughput Q. Using the delta pressure (P₁−P₂) and the flow Q, the flow conductance of the showerhead assembly 404 may be measured as Q/(P₁−P₂). The controller 422 may vary the pressure P₁ at the intake conduit 416b and measure flow conductance values at different pressure values. Based on these multiple flow conductance values, the controller 422 may generate overall flow characteristics of the showerhead assembly 404. The flow characteristics of the showerhead assembly 404 may also be referred to as a flow profile or a flow fingerprint of the showerhead assembly 404. The controller 422 may output the flow characteristics of the showerhead assembly 404 by displaying them on a screen, creating a computer-readable file, etc.

The controller 422 may compare the flow profile of the showerhead assembly 404 with a predetermined flow profile. The predetermined flow profile may be determined by a user as a set of minimum requirements that the showerhead assembly 404 must satisfy to be deemed adequate for being provided to a customer. If the controller 422 determines that the flow profile of the showerhead assembly 404 does not satisfy the predetermined flow profile, then the showerhead assembly 404 may be subject to another round of cleaning or be removed from circulation (e.g., depending on the severity of the deficiencies).

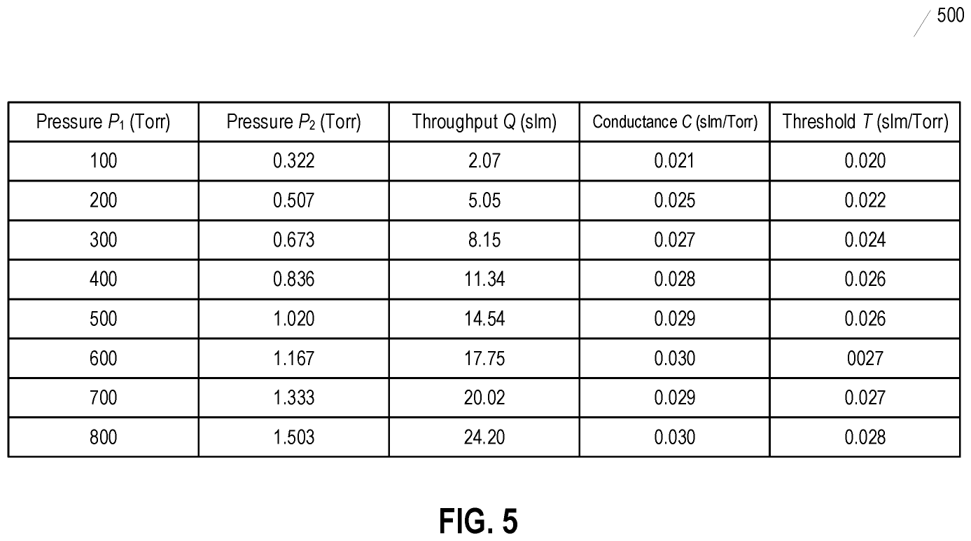

FIG. 5 shows an example flow profile of a showerhead assembly. A flow profile 500 may be a collection of data received from various components of the conductance test fixture. The flow profile 500 may represent the overall characteristics (e.g., fingerprint) of the showerhead assembly. For example, a controller (e.g., the controller 422) may receive the pressure values P₁ from a pressure controller (e.g., the pressure controller 414) and/or a pressure transducer (e.g., the pressure transducer 432). The controller may send commands to the pressure controller to maintain the intake gas pressure at various pressure values P₁. The controller may receive the pressure values P₂ from a pressure transducer (e.g., the pressure transducer 420a, the pressure transducer 420b, etc.). The controller may receive the flow throughput value Q from a pressure controller (e.g., the pressure controller 422). For each set of values (e.g., for each row), the controller may determine the conductance value C, e.g., according to the formula, C=Q/(P₁−P₂). The controller may compare the conductance values C with respective threshold values T. The threshold values T may represent a set of predetermined flow profile that a given showerhead assembly must satisfy. If one or more of the conductance values C do not satisfy the threshold values T, then the showerhead assembly may be deemed not meeting the standards. A showerhead assembly that falls short of the standards may require additional cleaning operation(s). If the showerhead assembly fails to meet the standards by a large margin (e.g., above a predetermined threshold), then the showerhead assembly may be taken out of circulation.

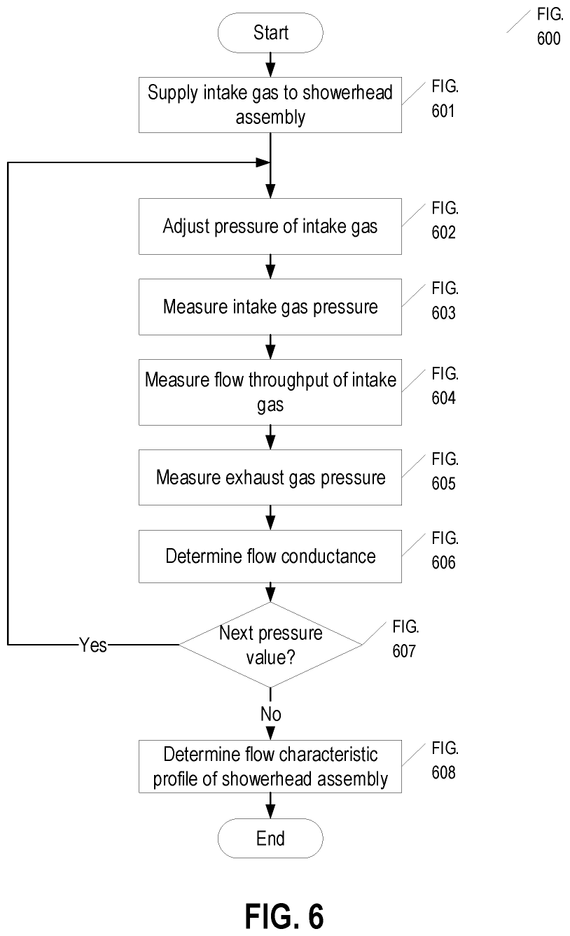

FIG. 6 shows an example flowchart 600 describing a process for measuring a flow conductance of a showerhead assembly. One, some, or all steps of the example process chamber volume adjustment method of FIG. 6 may be omitted, performed in other orders, and/or otherwise modified, and/or one or more additional steps may be added. For example, the measuring steps 603, 604, 605 may be performed concurrently or in any order. At step 601, intake gas may be supplied to a showerhead assembly. For example, the intake gas may be supplied from a gas source (e.g., 412) to the showerhead assembly (e.g., 404) via an intake conduit (e.g., 416). The intake conduit may be coupled to an intake port (e.g., 408) of the showerhead assembly. The showerhead assembly may be coupled to a blank-off plate (e.g., 406) to simulate a vacuum environment. Supplying the intake gas to the showerhead assembly may be caused by a controller (e.g., sending a command to a pressure controller) or manually performed by a user (e.g., by manipulating a mechanical valve).

At step 602, the pressure of the intake gas may be adjusted. The controller (e.g., 422) may send a command to a pressure controller (e.g., 414) coupled to the intake conduit to regulate the pressure of the intake gas. For example, the pressure controller may maintain the pressure of the intake conduit at a first pressure value. After the intake gas pressure is adjusted, the controller may wait for a predetermined amount of time such that the pressures may find an equilibrium.

At step 603, the intake gas pressure may be measured. The intake gas pressure may be measured by a pressure controller (e.g., 414) and/or a pressure transducer (e.g., 432) coupled to the intake conduit. The pressure controller and/or the pressure transducer may send the measured first pressure value to the controller. In some examples, if the controller is already aware of the first pressure value (e.g., if the controller sent a command to the pressure controller to maintain the pressure at the first pressure value), then step 603 may be omitted.

At step 604, a flow throughput of the intake gas may be measured. The flow throughput may be measured by the pressure controller coupled to the intake conduit. The flow throughput may be measured in as a mass throughput or as a pressure throughput having units of pressure times volume per second (e.g., slm). At step 605, the exhaust gas pressure may be measured. The exhaust gas pressure may be measured by a pressure transducer (e.g., 420) coupled to an exhaust conduit through which the exhaust gas is expelled from the showerhead assembly. The exhaust gas pressure may be measured by two or more pressure transducers (e.g., 420a, 420b), which may have different measurement ranges and/or resolutions.

At step 606, a flow conductance of the showerhead assembly may be determined. For example, the controller may determine the flow conductance based on the intake gas pressure, the flow throughput of the intake gas, and the exhaust gas pressure. For example, the controller may determine the conductance value C according to the formula, C=Q/(P₁−P₂), where Q represents the flow throughput of the intake gas, P₁ is the intake gas pressure, and P₂ is the exhaust gas pressure.

At step 607, the controller may determine whether there are any additional intake pressure value(s) at which a conductance value of the showerhead assembly needs to be measured. If there are one or more intake pressure values to measure the conductance value(s) at (607: Yes), then the process may return to step 602 to adjust the intake gas pressure to a new value, and determine a new flow conductance value (606). Otherwise (607: No), the controller may determine a flow characteristic profile of the showerhead assembly based on the flow conductance value(s). The flow characteristic profile may be output to the user. The output may be iteratively (e.g., in step 606), or in a single step (e.g., in step 608). The controller may further compare the flow characteristic profile of the showerhead assembly with a predetermined profile to determine whether the showerhead assembly meets the required standards. The showerhead assemblies that do not meet the standards may require additional cleaning operations and/or be removed from circulation.

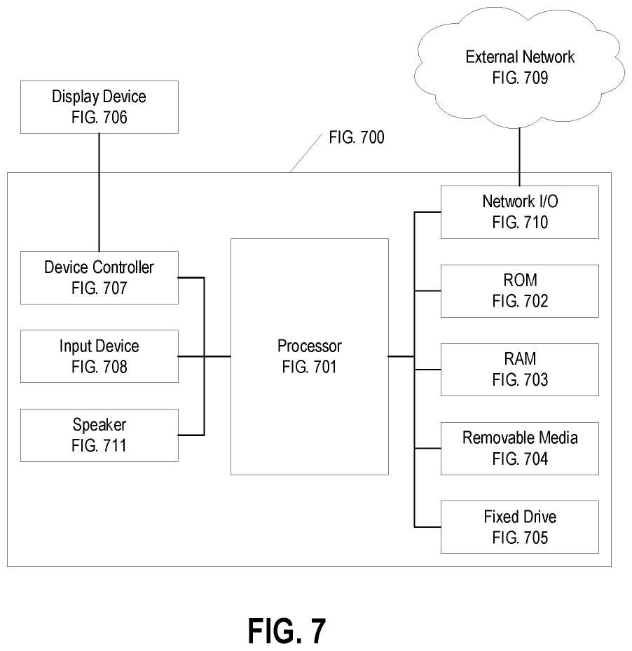

FIG. 7 shows an example system architecture of a device for controlling the systems (e.g., 300, 400a, 400b) and performing the processes (e.g., 600) described herein. For example, one or more devices and components as described herein (e.g., the controller 422) may be implemented with the device shown in FIG. 7. The term “network” as used herein and depicted in the drawings refers not only to systems in which remote storage devices are coupled together via one or more communication paths, but also to stand-alone devices that may be coupled, from time to time, to such systems that have storage capability. An example system architecture 700 may be used according to one or more illustrative aspects described herein. The system 700 may have a processor 701 for controlling overall operation of the system and its associated components, including read-only memory (ROM) 702, random access memory (RAM) 703, removable media 704, a fixed drive 705, a display device 707, a device controller 707, an input device 708, a network input/output device 710, and a speaker 711.

The input device 708 may include a mouse, keypad, touch screen, scanner, optical reader, and/or stylus (or other input device(s)) through which a user of the system 700 may provide input. One or more speakers 711 may provide audio output, and the display device 706 may provide textual, audiovisual, and/or graphical output. Software may be stored within the removable media 704 and/or the fixed drive 705 to provide instructions to processor 701 for configuring the system 700 into a special purpose computing device in order to perform various functions as described herein. For example, the removable media 704 and/or the fixed drive 705 may store software used by the system 700, such as an operating system, application programs, and/or an associated database.

The system 700 may operate in a networked environment supporting connections to one or more remote computers or components, such as the pressure controller 414, the pressure transducers 420, the pressure transducer 432, etc. The external network 709 may include a local area network (LAN) and a wide area network (WAN), but may also include other networks. When used in a LAN networking environment, the system 700 may be connected to the LAN through the network I/O 710 (e.g., a network interface or adapter). When used in a WAN networking environment, the system 700 may include a modem or other wide area network interface for establishing communications over the WAN, such as the Internet. It will be appreciated that the network connections shown are illustrative and other means of establishing a communications link between the computers may be used. The system 700 may be a mobile terminal (e.g., a mobile phone, a smartphone, a personal digital assistant (PDA), a laptop computer, etc.) including various other components, such as a battery, speaker, and antennas (not shown).

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A system comprising:
a housing;
a showerhead assembly seated in the housing, the showerhead assembly comprising an intake port and an exhaust port;
a gas source coupled to the intake port of the showerhead assembly, wherein the gas source is configured to supply gas to the showerhead assembly via the intake port;
a pressure controller coupled between the gas source and the showerhead assembly, wherein the pressure controller is configured to measure a flow throughput of the gas that passes through the pressure controller;
a pressure transducer coupled to the exhaust port of the showerhead assembly; and
a controller configured to:
cause the pressure controller to maintain the gas being supplied from the gas source to the showerhead assembly at a first pressure value;
receive, from the pressure transducer, a second pressure value; and
determine, based on the flow throughput, the first pressure value, and the second pressure value, a flow conductance of the showerhead assembly.

2. The system of claim 1, wherein the flow conductance is a first flow conductance, wherein the flow throughput is a first flow throughput, and
wherein the controller is further configured to:
cause the pressure controller to maintain the gas being supplied from the gas source to the showerhead assembly at a third pressure value;
receive, from the pressure controller, a second flow throughput;
receive, from the pressure transducer, a fourth pressure value;
determine, based on the second flow throughput, the third pressure value, and the fourth pressure value, a second flow conductance of the showerhead assembly; and
generate, based on the first flow conductance and the second flow conductance, a flow characteristic profile of the showerhead assembly.

3. The system of claim 1, wherein the showerhead assembly further comprises:
a showerhead comprising a plurality of apertures;
a transfer tube coupled between the intake port and the showerhead; and
a blank-off plate coupled to the showerhead to create a seal around the showerhead.

4. The system of claim 1, wherein the gas source is coupled to the intake port via at least one of a manual valve, a pressure regulator, a filter, or a second pressure transducer.

5. The system of claim 1, wherein the pressure transducer comprises a first pressure transducer and a second pressure transducer, wherein the pressure transducer and the second pressure transducer have different measurement ranges and different measurement resolutions.

6. The system of claim 1, wherein the controller is configured to determine the flow conductance based on a formula, C=Q/(P₁−P₂), wherein C is the flow conductance, Q is the flow throughput, P₁is the first pressure value, and P₂ is the second pressure value.

7. The system of claim 1, wherein the gas is an inert gas.

8. The system of claim 1, wherein the gas is at least one of nitrogen, ammonia, silane, hydrogen, argon, or krypton.

9. A flow conductance measuring device comprising:
a pressure controller configured to:
supply intake gas to a showerhead assembly at a first pressure value; and
measure a flow throughput of the supplied intake gas;
a pressure transducer configured to measure a second pressure value of an exhaust gas, which comprises the intake gas being expelled from the showerhead assembly;
a controller configured to determine a flow conductance of the showerhead assembly based on the flow throughput, the first pressure value, and the second pressure value.

10. The flow conductance measuring device of claim 9, wherein the intake gas is a first intake gas, wherein the exhaust gas is a first exhaust gas, wherein the flow throughput is a first flow throughput, wherein the flow conductance is a first flow conductance,
wherein the pressure controller is configured to:
supply a second intake gas to the showerhead assembly at a third pressure value; and
measure a second flow throughput of the supplied second intake gas,
wherein the pressure transducer is further configured to measure a fourth pressure value of a second exhaust gas, which is the second intake gas being expelled from the showerhead assembly, and
wherein the controller is further configured to:
determine a second flow conductance of the showerhead assembly based on the second flow throughput, the third pressure value, and the fourth pressure value; and
determine, based on the first flow conductance and the second flow conductance, a flow characteristic profile of the showerhead assembly.

11. The flow conductance measuring device of claim 9, wherein the pressure controller is coupled to a gas source via at least one of a manual valve, a pressure regulator, a filter, or a second pressure transducer.

12. The flow conductance measuring device of claim 9, wherein the pressure transducer comprises a first pressure transducer and a second pressure transducer, wherein the pressure transducer and the second pressure transducer have different measurement ranges and different measurement resolutions.

13. The flow conductance measuring device of claim 9, wherein the controller is configured to determine the flow conductance based on a formula, C=Q/(P₁−P₂), wherein C is the flow conductance, Q is the flow throughput, P₁ is the first pressure value, and P₂ is the second pressure value.

14. The flow conductance measuring device of claim 9, wherein the intake gas is an inert gas.

15. A method comprising:
causing, by a controller, an intake gas to be supplied to a showerhead assembly via an intake conduit at a first pressure value;
receiving an indication of a flow throughput of the intake gas;
receiving an indication of a second pressure value, of an exhaust gas being expelled from the showerhead assembly, measured at an exhaust conduit coupled to the showerhead assembly; and
determining, based on the flow throughput, the first pressure value, and the second pressure value, a flow conductance of the showerhead assembly.

16. The method of claim 15, further comprising:
based on the flow conductance failing to satisfy a threshold value, refurbishing the showerhead assembly.

17. The method of claim 15, wherein the flow conductance is a first flow conductance, wherein the flow throughput is a first throughput, and
wherein the method further comprises:
causing, by the controller, the intake gas to be supplied to the showerhead assembly via the intake conduit at a third pressure value;
receiving an indication of a second flow throughput of the intake gas;
receiving an indication of a fourth pressure value, of the exhaust gas being expelled from the showerhead assembly, measured at the exhaust conduit;
determining, based on the second flow throughput, the third pressure value, and the fourth pressure value, a second flow conductance of the showerhead assembly;
outputting for display, based on the first flow conductance and the second flow conductance, a flow characteristic profile of the showerhead assembly.

18. The method of claim 15, wherein the receiving the indication of the flow throughput of the intake gas comprises receiving the indication of the flow throughput of the intake gas from a flow controller coupled to the intake conduit, and wherein the receiving the indication of the second pressure value comprises receiving the indication of the second pressure value from a pressure transducer.

19. The method of claim 15, wherein the causing the intake gas to be supplied to the showerhead assembly comprises:
sending, by the controller to a pressure controller, a command to maintain the intake gas in the intake conduit at the first pressure value.

20. The method of claim 15, wherein the determining the flow conductance of the showerhead assembly comprises determine the flow conductance based on a formula, C=Q/(P₁−P₂), wherein C is the flow conductance, Q is the flow throughput, P₁ is the first pressure value, and P₂ is the second pressure value.
